(19) United States
(12) Patent Application Publication
(10) Pub. No.: US 2021/0104584 A1
(43) Pub. Date: Apr. 8, 2021

(54) LIGHT-EMITTING PANEL AND METHOD OF MANUFACTURING THE SAME

(71) Applicant: INT TECH CO., LTD., Hsinchu County (TW)

(72) Inventors: YUAN-CHING CHANG, YILAN COUNTY (TW); CHENG-HSIN CHEN, HSINCHU COUNTY (TW)

(21) Appl. No.: 16/593,662

(22) Filed: Oct. 4, 2019

(51) Int. Cl. H01L 27/32; H01L 51/52

(52) U.S. Cl. CPC H01L 27/3244; H01L 2227/323; H01L 51/5237

(57) ABSTRACT

A method of manufacturing a light-emitting panel includes forming a plurality of transistors on a substrate, forming an ILD on the substrate to cover the transistors; and forming a plurality of first through holes penetrating the ILD to partially expose the transistors. The method further includes forming a plurality of conductive features on the ILD and in the first through holes to electrically connect the transistors; forming a first passivation layer on the ILD to cover the conductive features; and planarizing the first passivation layer. The method further includes forming a second through hole penetrating the first passivation layer to partially expose one of the conductive features; and forming a light-emitting device on the planarized first passivation layer, wherein the light-emitting device includes a first electrode formed on the planarized first passivation layer and in the second through hole to electrically connect the exposed conductive feature.

### TECHNICAL FIELD

The present disclosure is related to a light-emitting panel and a method of manufacturing the same, and especially to an organic light-emitting panel and the method of manufacturing the same.

### BACKGROUND

Organic light-emitting diodes (OLED) have been widely used in high-end electronic devices, especially the active matrix type OLED (AMOLED). Each light-emitting element, or pixel, in the AMOLED is independently controlled by a thin-film transistor (TFT). However, due to the constraints of current technology, achieving a pixel density of 800 ppi or higher becomes a difficult task for a display manufacturer.

### SUMMARY

In some embodiments of the present disclosure, a method of manufacturing a light-emitting panel is provided. The method includes forming a plurality of transistors on a substrate, forming an inter-layer dielectric (ILD) on the substrate to cover the transistors; and forming a plurality of first through holes penetrating the ILD to partially expose the transistors. The method further includes forming a plurality of conductive features on the ILD and in the first through holes to electrically connect the transistors; forming a first passivation layer on the ILD to cover the conductive features; and planarizing the first passivation layer. The method further includes forming a second through hole penetrating the first passivation layer to partially expose one of the conductive features; and forming a light-emitting device on the planarized first passivation layer, wherein the light-emitting device comprises a first electrode, a light-emitting layer on the first electrode, and a second electrode on the light-emitting layer, and wherein the first electrode is formed on the planarized first passivation layer and in the second through hole to electrically connect the exposed conductive feature.

In some embodiments of the present disclosure, a method of manufacturing a light-emitting panel is provided. The method includes forming a plurality of transistors on a substrate, forming an inter-layer dielectric (ILD) on the substrate to cover the transistors; and planarizing the ILD. The method further includes forming a plurality of first through holes penetrating the ILD to partially expose the transistors; forming a plurality of conductive features on the ILD and in the first through holes to electrically connect the transistors; and forming a first passivation layer on the ILD to cover the conductive features. The method further includes planarizing the first passivation layer; forming a second through hole penetrating the first passivation layer to partially expose one of the conductive features; and forming a light-emitting device on the first passivation layer, wherein the light-emitting device comprises a first electrode, a light-emitting layer on the first electrode, and a second electrode on the light-emitting layer, and wherein the first electrode is formed on the first passivation layer and in the second through hole to electrically connect the exposed conductive feature.

In some embodiments of the present disclosure, a light-emitting panel is provided. The light-emitting panel includes a circuit level and a light-emitting device. The circuit level includes a passivation layer, and the passivation layer includes an inorganic dielectric material. The light-emitting device is disposed on a top surface of the passivation layer and electrically connected to the circuit level.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a top view of a light-emitting panel in accordance with some embodiments of the present disclosure.

FIG. 2 is an electrical circuit diagram of a pixel-driving circuit in accordance with some embodiments of the present disclosure.

FIGS. 3 to 12 are cross-sectional views illustrating exemplary operations for manufacturing a light-emitting panel according to another embodiment of the present disclosure.

FIGS. 13 to 16 are cross-sectional views illustrating exemplary operations for manufacturing a light-emitting panel according to another embodiment of the present disclosure.

FIGS. 17 to 25 are cross-sectional views illustrating exemplary operations for manufacturing a light-emitting panel according to another embodiment of the present disclosure.

FIG. 26 to FIG. 27 are cross-sectional views along the line A-A′ in FIG. 1 illustrating several operations of a method of manufacturing of a light-emitting panel in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the term “about” generally means within 10%, 5%, 1%, or 0.5% of a given value or range. Alternatively, the term “about” means within an acceptable standard error of the mean when considered by one of ordinary skill in the art. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the term “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides a method of manufacturing a light-emitting panel. In the present disclosure, the light-emitting panel is manufactured by operations including a planarization process. The planarization process improves the flatness of the landing surfaces for subsequent layers, and thus increases the pattern accuracy of subsequent layers.

A light-emitting panel is constructed to have at least two major units. One unit is configured as a light-emitting device including an array of light-emitting pixels and provides luminescence for the device. The light-emitting pixels can be made with organic or inorganic material. Another unit is a circuit level which is electrically coupled to the light-emitting level and vertically stacked with the light-emitting device. The circuit level supplies power and control signals to the light-emitting device in order to display the color or pattern as needed.

In order to combine and electrically couple the two major units to form an integrated light-emitting panel, various approaches can be adopted. One of the approaches includes first forming the circuit level, then forming the light-emitting device over the circuit level. The circuit level acts as a substrate for forming the light-emitting device thereon. Another exemplary approach includes independently forming the circuit level and the light-emitting device on separate substrates, then bonding the circuit level and the light-emitting device to form an integrated light-emitting panel. However, regardless of which approach is chosen, as the pixel density of the light-emitting device increases and the light-emitting panel includes greater amounts of circuitry and pixels, the flatness of each side is critical to the manufacturing yield of the integrated light-emitting panel.

The present disclosure provides a method of manufacturing a light-emitting panel, which includes at least one planarization to form a flat surface in the circuit level in order to improve the flatness of the landing surfaces. In some embodiments, the method forms a flat uppermost surface for the circuit level. The flat uppermost surface is a starting surface on which a light-emitting device including an array of light-emitting pixels is formed.

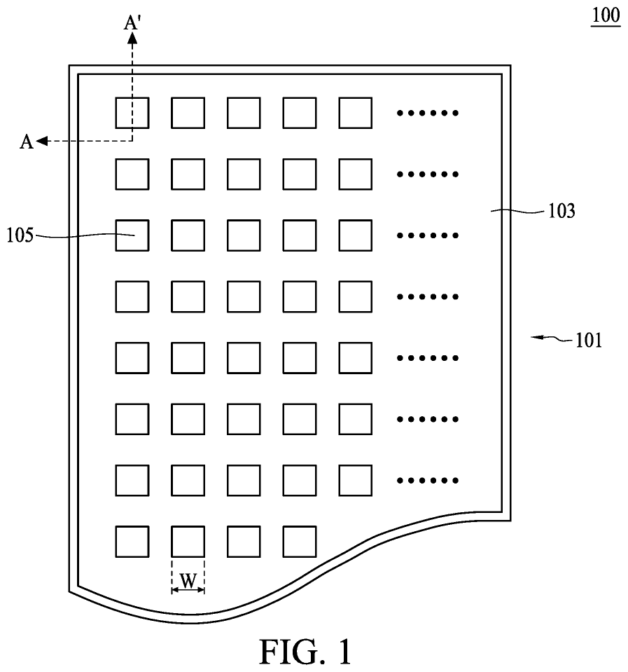

Referring to FIG. 1, FIG. 1 is a top view of a portion of a light-emitting panel 100, in accordance with some embodiments of the present disclosure. The light-emitting panel 100 can be a rigid or a flexible display. In some embodiments, the light-emitting panel 100 may include a substrate 101 and a light-emitting layer 103 disposed on the substrate 101. In some embodiments, several conductive traces may be disposed in the substrate 101 and form circuitry to provide current to the light-emitting layer 103. In some embodiments, the substrate 101 may include a TFT (thin-film transistor) array.

In some embodiments, the light-emitting layer 103 may include many light-emitting units 105. In some embodiments, the light-emitting units 105 may also be referred to as light-emitting pixels or pixels.

In some embodiments, the light-emitting units 105 are configured as mesas disposed on the substrate 101. In some embodiments, the light-emitting units 105 are configured to be in recesses of the substrate 101. In some embodiments, the light-emitting units 105 can be arranged in an array. Each independent light-emitting unit 105 is separated from other adjacent light-emitting units 105. In some embodiments, the separation distance between two adjacent light-emitting units is between about 2 nm and about 100 μm. In some embodiments, the separation distance is limited to no greater than about 50 μm so that the density of the light-emitting units 105 can be at least 700 ppi or 1200 ppi. In some embodiments, a light-emitting unit 105 has a width, w, between about 2 nm and about 500 μm. In some embodiments the width, w, is not greater than about 2 μm.

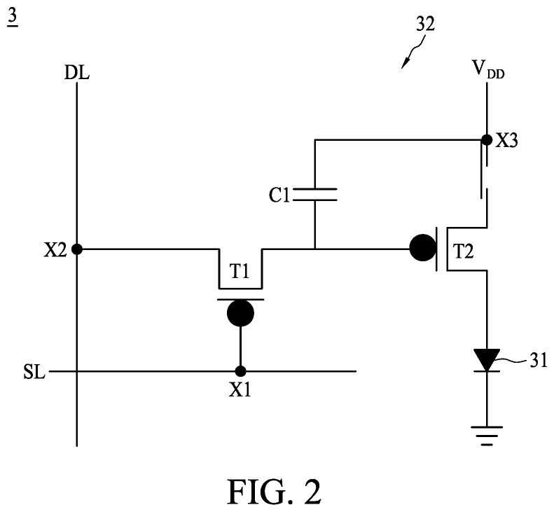

In some embodiments, the light-emitting panel 100 utilizes a plurality of pixel-driving circuits that are arranged in matrices in the substrate 101 and that can emit light of different colors to achieve the function of displaying images. With reference to FIG. 2, in some embodiments, a pixel-driving circuit 3 includes a light-emitting unit 31 and a driving portion 32. The driving portion 32 is configured to send a driving current through the light-emitting unit 31. The light-emitting unit 31 is driven by the driving current from the driving portion 32 to emit light with a luminance that corresponds to a magnitude of the driving current. In some embodiments, the light-emitting unit 31 includes an OLED.

Various kinds of circuits can serve as the driving circuit for driving the light-emitting unit 31, and the driving portion 32 can adopt a configuration having a driving circuit that includes a plurality of transistors and at least one storage capacitor. By way of example, the driving circuit can include a drive configuration indicated as a 5T/1C type, a 4T/1C type, a 3T/1C type, a 2T/1C type or the like, where T represents a transistor and C represents a storage capacitor.

In some embodiments, the 2T/1C type drive configuration is adopted in the pixel-driving circuit 3. The driving portion 32 includes a first transistor T1, a second transistor T2, and a storage capacitor C1. Each of the first and second transistors T1, T2 includes a first terminal, a second terminal, and a gate terminal. Each of the first and second transistors T1, T2 can be a P-channel transistor or an N-channel transistor.

The gate terminal of the first transistor T1 is coupled to a scan line SL at a node X1 configured for receiving a scan signal from the scan line SL. The first terminal of the first transistor T1 is coupled to a data line DL at a node X2 for receiving a data signal from the data line DL. The second terminal of the first transistor T1, the gate terminal of the second transistor T2, and one end of the storage capacitor C1 are electrically connected. The other end of the storage capacitor C1 is coupled to a V_{DD} line V_{DD} at a node X3. The first terminal of the second transistor T2 is coupled to the V_{DD} line V_{DD} at the node X3. The second terminal of the second transistor T2 is electrically coupled to the light-emitting unit 31.

Although not illustrated in the figures, a substrate 101 may include a plurality of the pixel-driving circuits 3, which are two-dimensionally disposed in a matrix. That is, a plurality of vertical scan lines SL are wired so as to correspond to the rows for the pixel-driving circuits 3, and a plurality of data lines DL are wired so as to correspond to the columns for the pixel-driving circuits 3.

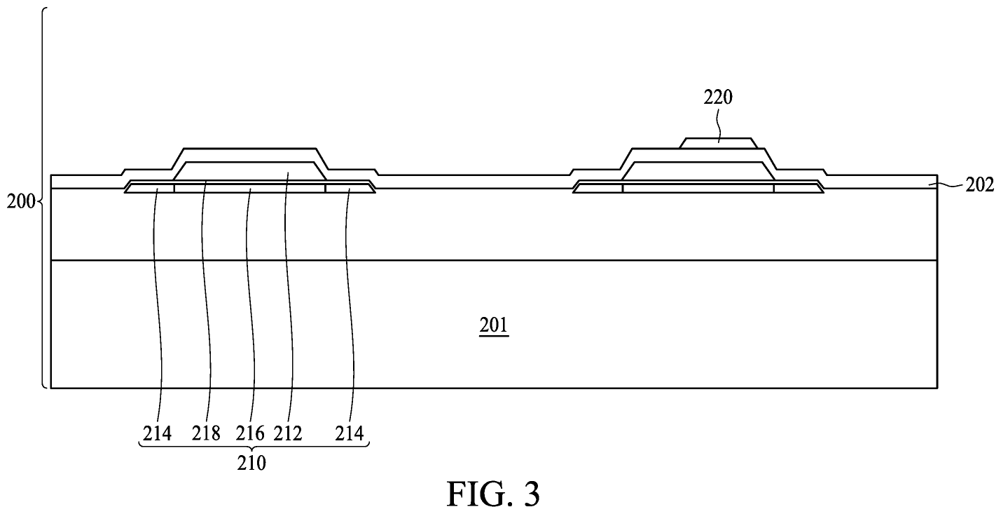

Cross-sectional views along the line A-A′ in FIG. 1 are illustrated in FIG. 3 to FIG. 27. FIG. 3 to FIG. 12 illustrate exemplary operations of a method of manufacturing a light-emitting panel, in accordance with some embodiments of the present disclosure, wherein FIG. 3 to FIG. 11 illustrate several operations of manufacturing a circuit level 200.

FIG. 3 illustrates a plurality of transistors 210 formed on a substrate 201. The substrate 201 may include a transparent substrate or an opaque substrate. In some embodiments, the substrate 201 includes glass, a semiconductive material such as silicon, a III-V group compound, graphene or other suitable material.

In some embodiments, the substrate 201 is flexible. The substrate 201 may include a polymer matrix material. The substrate 201 may have, but is not limited to having, a bend radius not greater than about 3 mm. In some embodiments, the substrate 201 may be a rectangular substrate. In some other embodiments, the substrate may be a round substrate, which is compatible with semiconductor fabrication.

In some embodiments, the transistors 210 are configured to drive a light-emitting device. Each transistor 210 includes a gate 212 over a channel 216. The gate 212 can be made with conductive material such as metal or silicide. The channel 216 may be made with semiconductive material such as silicon or other element selected from group IV, or groups III and V. Source/drain regions 214 are disposed on opposite sides of the channel 216 to provide carriers. Further, in the transistor 210, a gate dielectric 218 is disposed between the gate 212 and the channel 216. In some embodiments, the gate dielectric 218 may include silicon oxide, ONO (silicon oxide-silicon nitride-silicon oxide), or a high-k dielectric with a dielectric constant greater than 10 or 12, such as hafnium silicate, zirconium silicate, hafnium dioxide, zirconium dioxide, etc.

In some embodiments, the two transistors 210 are configured to serve as the first and second transistors T1, T2 shown in FIG. 2. FIG. 3 illustrates only two transistors 210 for clarity and simplicity, but such example is intended to be illustrative only, and is not intended to be limiting to the embodiments. A person ordinarily skilled in the art would readily understand. It is contemplated that any suitable number of the transistors 210 may be utilized, and all such combinations are fully intended to be included within the scope of the embodiments. Additionally, while the transistors 210 are illustrated as having similar features, this is intended to be illustrative and is not intended to limit the embodiments, as the transistors 210 may have similar structures or different structures in order to meet the desired functional capabilities.

In some embodiments, a storage electrode 220 is formed on one of the transistors 210. In some embodiments, the storage electrode 220 and the gate 212 under the storage electrode 220 serve as a storage capacitor C1 as shown in FIG. 2. In some embodiments, a dielectric layer 202 is formed between the transistors 210 and the storage electrode 220, and serves as a capacitor dielectric. Charges may be stored in the dielectric layer 202 as needed. The dielectric layer 202 may include silicon oxide, silicon nitride, silicon oxynitride, etc.

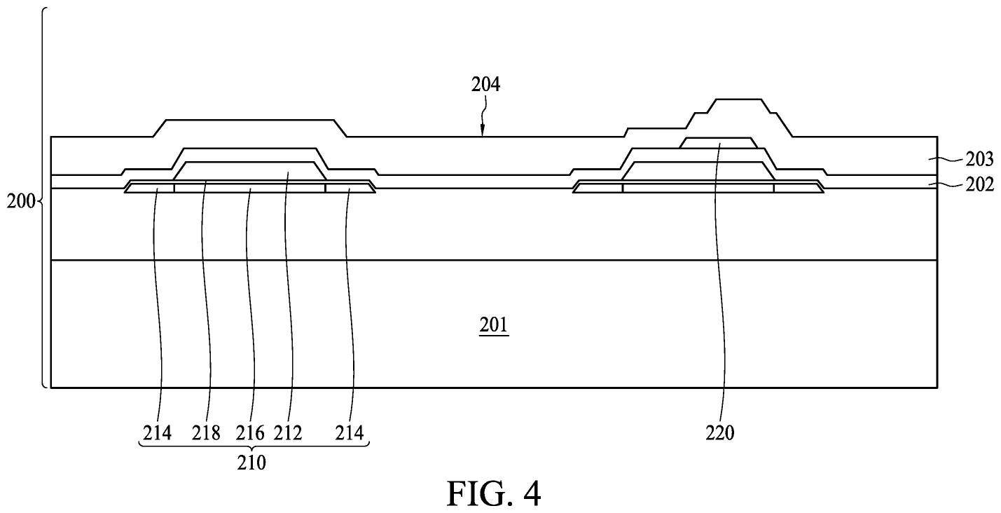

FIG. 4 illustrates the inter-layer dielectric (ILD) 203 formed on the substrate 201 to cover the transistors 210 and the storage electrode 220. The ILD 203 is conformal to the topography of the transistors 210 and the storage electrode 220 disposed over substrate 201. Therefore, a top surface 204 of the ILD 203 can be undulating and follows the topography of the transistors 210 and the storage electrode 220. In some embodiments, the ILD 203 includes an inorganic dielectric material. An example of the material of the ILD 203 includes silicon nitride, which is more resistant to moisture and acid than an organic dielectric material. The material of the ILD 203 may include other inorganic or organic materials. In some embodiments, thickness of the ILD 203 is not uniform. In some embodiments, the ILD 203 may include more than one layer.

Formation of the dielectric layer 202 and the ILD 203 may include performing a deposition operation such as atomic layer deposition (ALD), chemical vapor deposition (CVD) or the like.

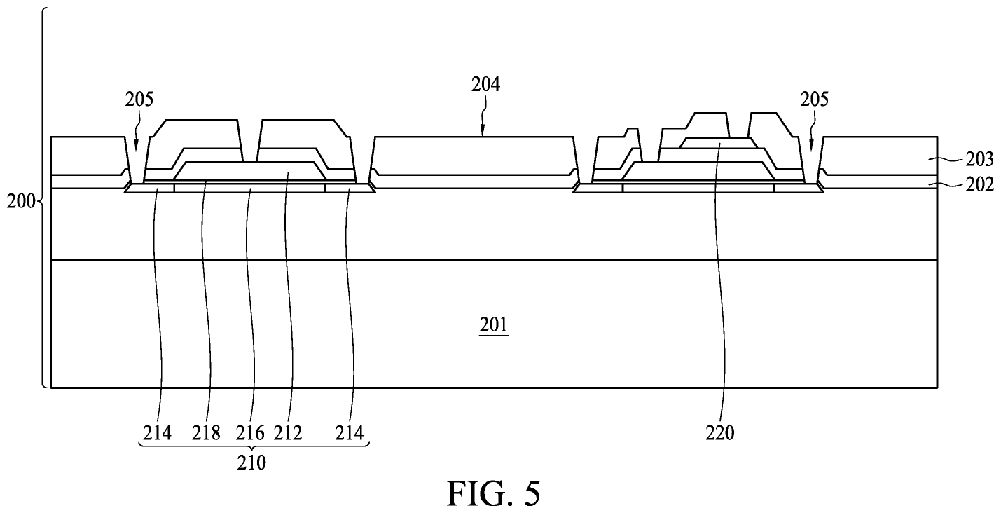

Referring to FIG. 5, the first through holes 205 are formed in the ILD 203 to partially expose the transistors 210. The predetermined portions of the transistors 210 and the storage electrode 220 may be exposed using a suitable photolithographic mask and etching process, although any suitable process may be used.

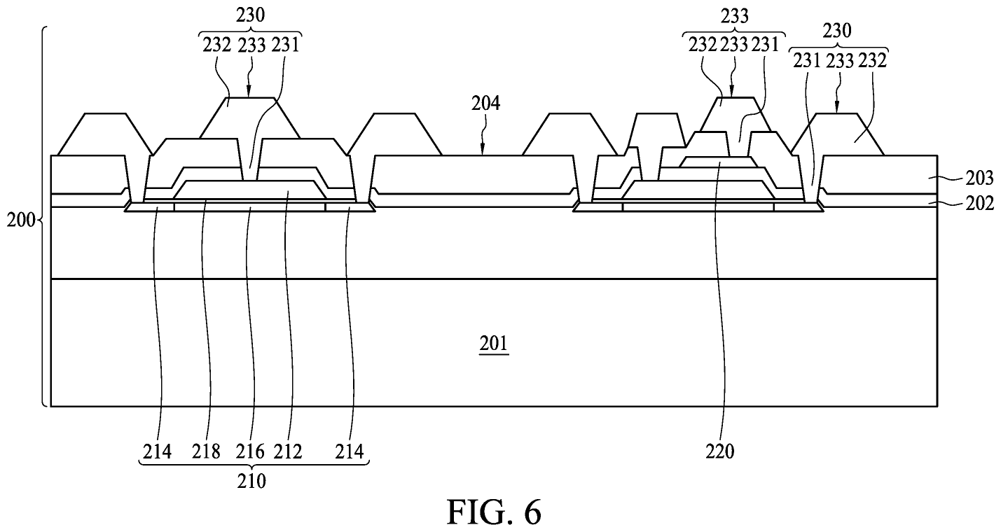

Referring to FIG. 6, the conductive features 230 are formed on the ILD 203 and in the first through holes 205 to electrically connect the transistors 210 and the storage electrode 220. The ILD 203 is disposed between the transistors 210 and the conductive features 230. The conductive features 230 may be formed by various deposition techniques such as PVD, which are followed by various patterning techniques. The conductive feature 230 may be single-layered or multi-layered. In some embodiments, the conductive feature 230 may include a stack of a seed layer, a bottom barrier layer, a conductive layer and a top barrier layer. By way of example, the material of the seed layer may include titanium (Ti), the material of the bottom barrier layer and the top barrier layer may include titanium nitride (TiN), and the material of the conductive layer may include aluminum-copper (AlCu) alloy. In some embodiments, the patterning technique includes depositing a mask layer and removing portions not covered by the mask layer through a suitable etching process. In some embodiments, the top surfaces 233 of the conductive features 230 can be undulating and follow the topography of the ILD 203. That is, when the ILD 203 is not flat, the conductive feature 230 may be formed at different heights. In some embodiments, the conductive features 230 include conductive traces 232 on the ILD 203 and across various pixels, and conductive vias 231 in the first through holes 205. In some embodiments, the conductive traces 232 have similar thicknesses.

The conductive features 230 may include conductive vias 231, which penetrate through the ILD 203 and are connected at one end to the source/drain regions 214 of the transistor 210. The conductive features 230 may include conductive vias 231, which are connected at one end to the gate 212 of the transistor 210 or the storage electrode 220.

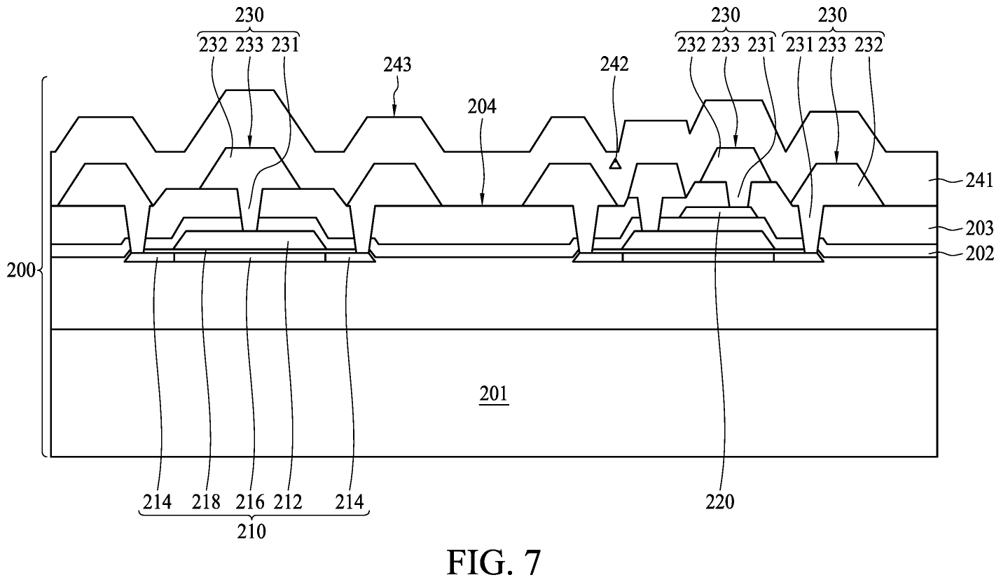

Referring to FIG. 7, the first passivation layer 241 is formed on the ILD 203 to cover the conductive features 230. In some embodiments, the first passivation layer 241 is substantially conformal to the conductive features 230 and the exposed ILD 203 in order to provide better protection to the conductive traces 232. Therefore, similar to the ILD 203, a top surface 243 of the first passivation layer 241 is undulating and follows the topography of conductive traces 232 and the exposed ILD 203 thereunder. In some embodiments, the surface of the first passivation layer 241 is uniform.

In some embodiments, the forming of the first passivation layer 241 includes performing a deposition operation such as ALD, CVD or the like. Because the distance between the adjacent conductive traces 232 is small, an undesired void 242 may exist in the first passivation layer 241.

In some embodiments, the first passivation layer 241 includes an inorganic dielectric material in order to be resistant to moisture and acid during subsequent etch operations. The first passivation layer 241 may be made with silicon oxide, silicon nitride, silicon oxynitride, or other suitable materials. In some embodiments, the inorganic dielectric material has a higher resistance to O₂ plasma than an organic dielectric material. In some embodiments, the inorganic dielectric material has a higher resistance to a PR stripping solution than an organic dielectric material. Compared to the ILD 203, the first passivation layer 241 has a greater capability to fill gaps. Therefore, the planarization layer 242 may fill the recess between the adjacent conductive features 230 to minimize the chance of formation of voids 242. In some other embodiments, the first passivation layer 241 includes an organic dielectric material.

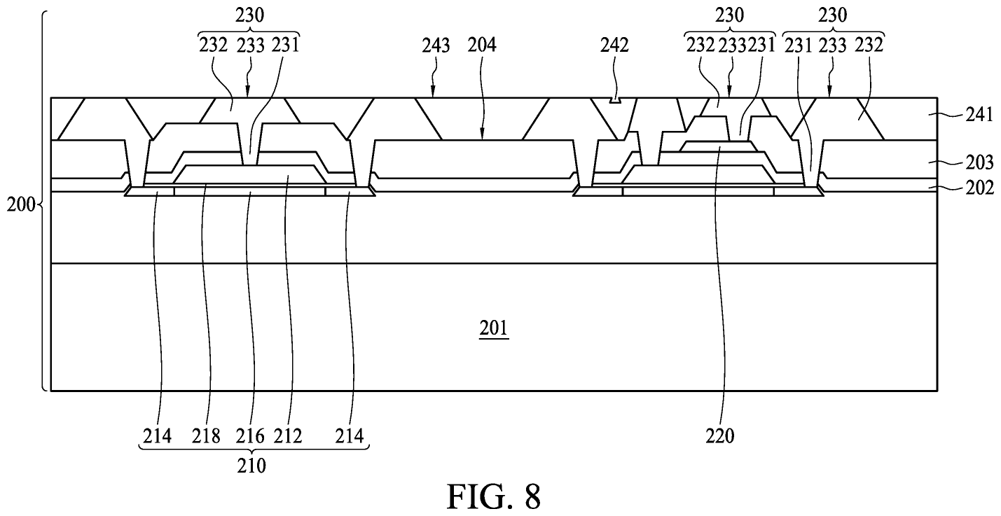

In order to provide a flat surface for subsequent operations, as shown in FIG. 8, the first passivation layer 241 is planarized. The first passivation layer 241 may be planarized using a suitable planarizing process, although any suitable process may be used. In some embodiments, planarizing the first passivation layer 241 includes performing a chemical-mechanical planarization (CMP) operation. The top surface 243 of the planarized first passivation layer 241 is flat and has a minimized roughness. In some embodiments, the top surface 243 of the planarized first passivation layer 241 has a surface roughness less than or equal to 100 Å. The surface roughness presented on the top surface 243 may be, for example but not limited to, the arithmetic average roughness Ra. As another example, the surface roughness presented on the top surface 243 may be represented by other surface roughness parameters such as the root mean squared roughness Rq, the maximum peak-to-valley height Ry, the average peak-to-valley roughness Rtm, or other types of surface roughness parameters.

In some embodiments, the top surfaces 233 of the conductive features 230 are exposed through the first passivation layer 241 subsequent to the planarizing of the first passivation layer 241. In some embodiments, the top surfaces 233 of the conductive features 230 are at the same level as, and exposed through, the planarized first passivation layer 241. In some embodiments, the top surfaces 233 of the conductive features 230 are coplanar with the top surface 243 of the planarized first passivation layer 241. In such cases, the top surfaces 233 of the conductive features 230 may also have surface roughness less than or equal to 100 Å. In some embodiments, portions of the conductive traces 232 of the conductive features 230 are removed simultaneously with the first passivation layer 241 during the planarizing of the first passivation layer 241. For example, the top barrier layer of the conductive feature 230 may be partially or entirely removed.

In some embodiments, the void 242 may be removed or exposed after the planarizing operation.

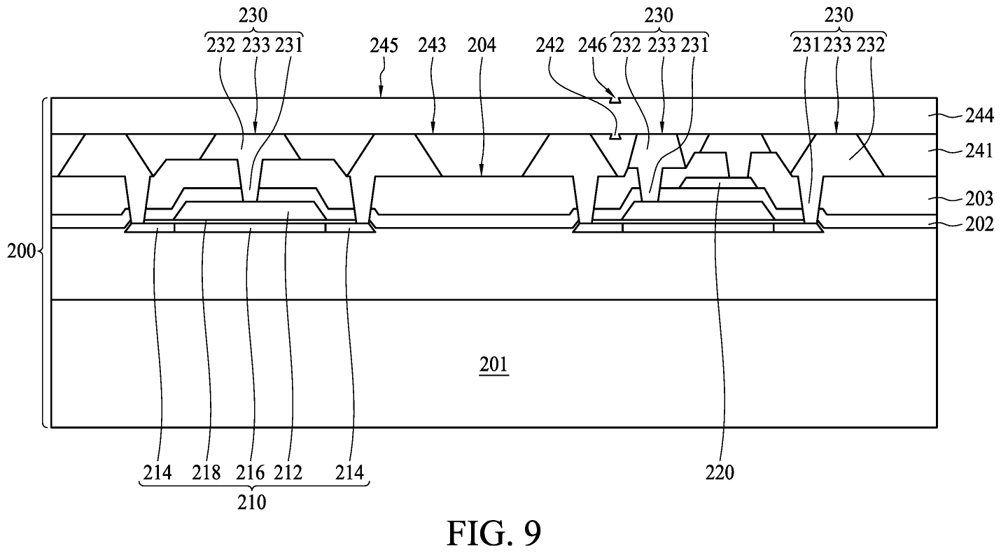

Referring to FIG. 9, in some embodiments, a second passivation layer 244 is formed on the planarized first passivation layer 241 and the conductive features 230. In some embodiments, the forming of the second passivation layer 244 includes performing a deposition operation such as ALD, CVD or the like. In some embodiments, formation of the second passivation layer 244 includes performing a CVD operation. The second passivation layer 244 is conformal to the topography of the planarized first passivation layer 241. The exposed void 242 can be filled during the formation of the second passivation layer 244. Therefore, a top surface 245 of the second passivation layer 244 can be undulating and follows the topography of the planarized first passivation layer 241. In some embodiments, when the planarized first passivation layer 241 includes the exposed void 242 on the top surface 243, a recess 246 may be included on the top surface 245 of the second passivation layer 244. In some embodiments, thickness of the second passivation layer 244 is uniform.

In some embodiments, the second passivation layer 244 includes inorganic dielectric material in order to be resistant to moisture and acid during subsequent etch operations. The second passivation layer 244 may be made with silicon oxide, silicon nitride, silicon oxynitride, or other suitable materials. In some embodiments, the first passivation layer 241 and the second passivation layer 244 include the same material. In some embodiments, the second passivation layer 244 includes a material different from that of the first passivation layer 241.

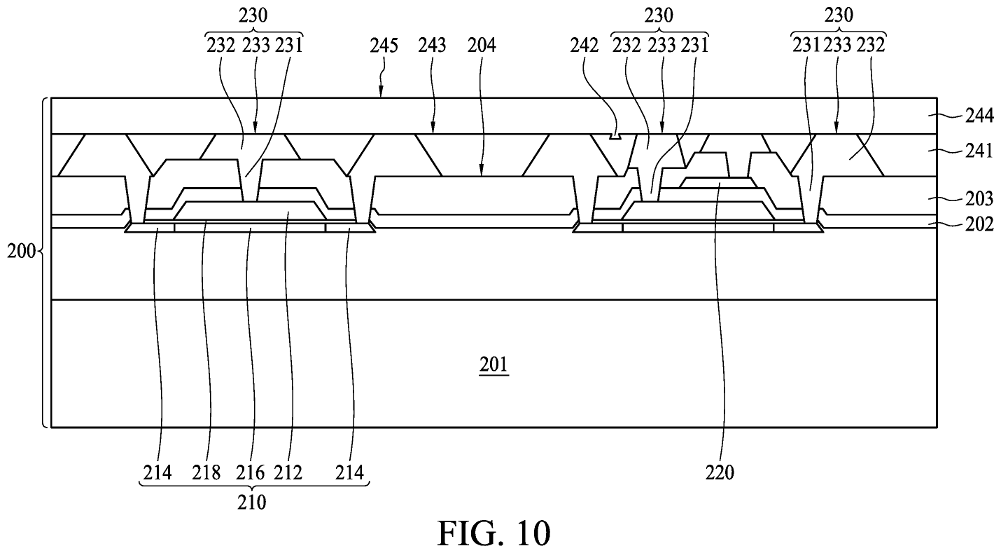

In order to provide a flat surface for subsequent operations, in some embodiments, as shown in FIG. 10, the second passivation layer 244 is planarized. The second passivation layer 244 may be planarized using a suitable planarizing process, although any suitable process may be used. In some embodiments, planarizing the second passivation layer 244 includes performing a CMP operation. The top surface 245 of the planarized second passivation layer 244 is flat and has a minimized roughness. In some embodiments, the top surface 245 of the planarized second passivation layer 244 has a surface roughness less than or equal to 100 Å.

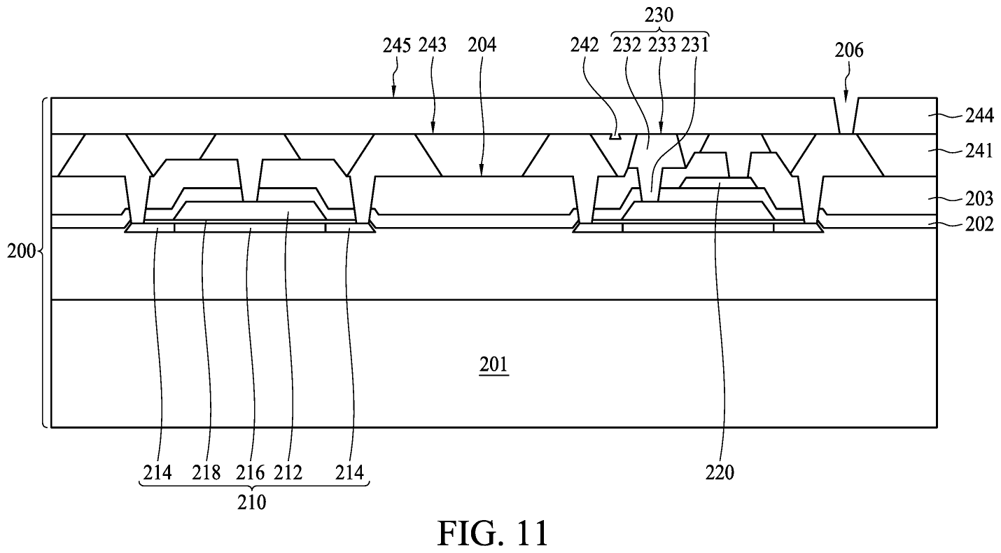

Referring to FIG. 11, in some embodiments, the second through hole 206 is formed in the planarized second passivation layer 244 and penetrates the planarized second passivation layer 244. The second through hole 206 may be formed using a suitable photolithographic mask and etching process, although any suitable process may be used. Since the top surface 245 of the planarized second passivation layer 244 is flat, the second through hole 206 may be more easily formed at the correct predetermined position. In some embodiments, the second through hole 206 partially exposes the top surface 233 of one of the conductive features 230. In some embodiments, the second through hole 206 partially exposes the top surface 233 of the conductive feature 230 electrically connected to the source/drain region 214 of the transistor 210 on which the storage electrode 220 is formed. In some embodiments, the circuit level 200 is formed.

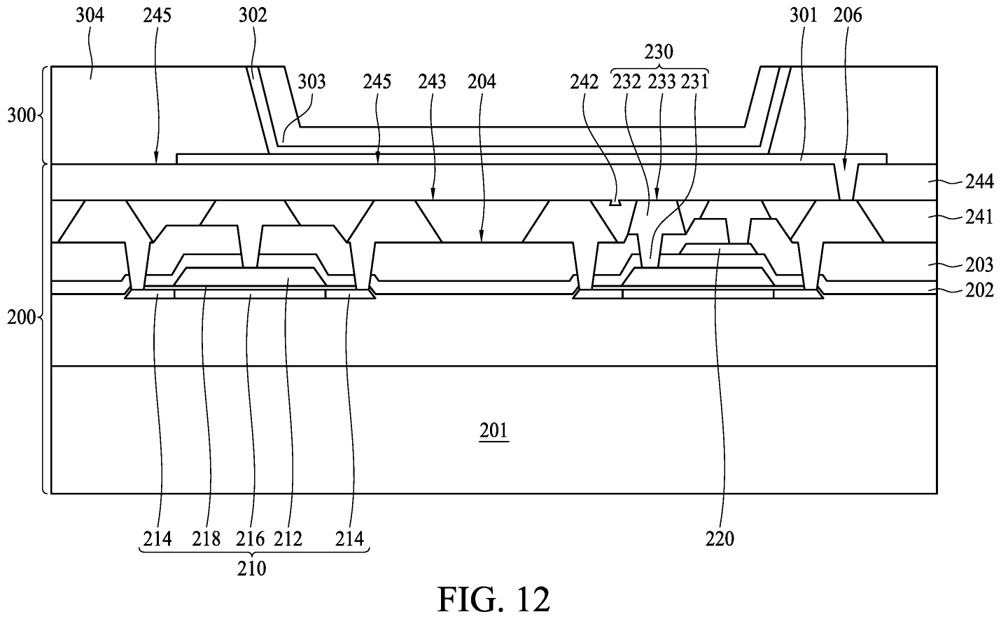

Referring to FIG. 12, the light-emitting device 300 is formed on circuit level 200 to form the light-emitting panel. To be specific, the light-emitting device 300 is formed on the planarized second passivation layer 244. In some embodiments, the light-emitting device 300 includes a first electrode 301, a light-emitting layer 302 on the first electrode 301, and a second electrode 303 on the light-emitting layer 302. The first electrode 301 is formed on the planarized second passivation layer 244 and in the second through hole 206 to electrically connect the exposed conductive feature 230. In some embodiments, the first electrode 301 is formed on and in contact with the top surface of the circuit level 200, such as the top surface 245 of the planarized second passivation layer 244. In some embodiments, no organic passivation layer is disposed between the first electrode 301 and the second passivation layer 244. In some embodiments, the light-emitting device 300 further includes a spacer (also known as a pixel-defining layer (PDL)) 304. In some embodiments, the light-emitting device 300 further includes a cover layer (not shown) to cover the spacer 304 and the second electrode 303.

In some embodiments, a conductive material is disposed over the planarized second passivation layer 244 and fills the second through hole 206. Examples of the conductive material include Al, Cu, Ag, Au, W and metal alloys. In some embodiments, the conductive material is a transparent metal oxide such as indium tin oxide (ITO), indium zinc oxide (IZO), aluminum-doped zinc oxide (AZO) or indium-doped cadmium oxide. In some embodiments, the conductive material is in direct contact with the planarized second passivation layer 244.

In some embodiments, the conductive material is patterned to form several electrodes 301. The pattern of the first electrode array may be designed in accordance with the designed pixel arrangement. In FIG. 12, only one electrode 301 is illustrated. The electrode 301 is configured to be connected to a conductive feature 230 embedded in the circuit level 200 at one side and to be in contact with a light-emitting material at the other side. In some embodiments, the electrode 301 is designed as an anode of the light-emitting unit. In some embodiments, the light-emitting unit is an organic light-emitting unit.

In some embodiments, the electrode 301 is patterned by dry etching. The inorganic dielectric material included in the second passivation layer 244 is resistant to damage caused by O₂ plasma, the by-product of dry etching such as hydrochloric acid, or the photoresist stripping solution.

After the forming of the electrode 301, the spacer 304 can be optionally disposed over the planarized second passivation layer 244. In some embodiments, the spacer 304 partially covers the first electrode 301 and leaves a portion of the first electrode 301 exposed to receive a light-emitting material. The spacer 304 may include polymeric material. In some embodiments, the spacer 304 includes photosensitive material. In some embodiments, the spacer 304 includes a photo absorption material. In some embodiments, the spacer 304 is used as a pattern-defined layer (PDL). The spacer 304 may be formed through a photolithography operation.

In some embodiments, a light-emitting material is disposed on the exposed portion of the first electrode 301 to form the light-emitting layer 302. In some embodiments, the light-emitting layer 302 is configured to serve as a first carrier-injection layer disposed over the exposed surfaces of the spacer 304 and the first electrode 301. In some embodiments, the first carrier-injection layer is continuously lined along the exposed surfaces of the spacer 304 and the first electrode 301. More specifically, the exposed portion of the electrode 301 is configured as an effective light-emitting area for one light-emitting unit. In some embodiments, the light-emitting layer 302 continuously overlies several spacers 304 and the electrode 301. The light-emitting layer 302 is optionally in contact with the spacers 304. The light-emitting layer 302 may be in contact with the first electrodes 301. In some embodiments, the light-emitting layer 302 includes an organic light-emitting material.

The light-emitting layer 302 may include several sublayers stacked over the first electrode 301. In some embodiments, a thickness of a sublayer in the light-emitting layer 302 is of nanometer scale and thicknesses of the first passivation layer 241 and the second passivation layer 244 are of micrometer scale. As a result, the flatness of the first passivation layer 241 and the second passivation layer 244 is critical to the performance of the light-emitting layer 302.

In some embodiments, the first electrode 301 and the second electrode 303 are employed as the anode and the cathode, respectively, of the light-emitting device 300.

In some embodiments, after the formation of the second passivation layer 244, the second through hole 206 is formed in the second passivation layer 244 to penetrate the second passivation layer 244, the second through hole 206 partially exposes the top surface 233 of one of the conductive feature 230, and no extra planarization is needed. The second passivation layer 244 is conformal to the topography of the planarized first passivation layer 241, and the top surface 245 of the second passivation layer 244 is flat enough to allow the light-emitting device 300 to be formed directly thereon.

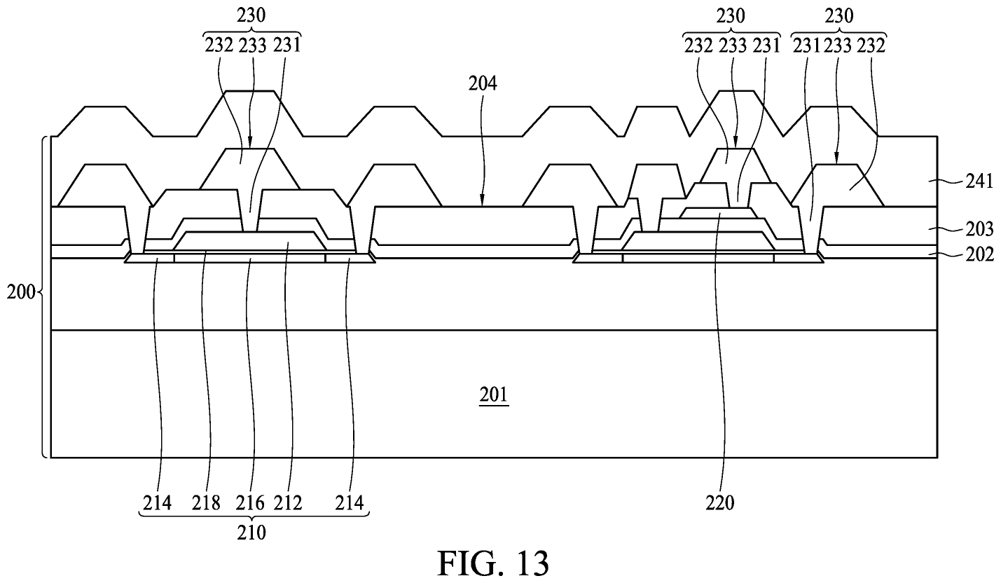

FIGS. 13 to 16 are cross-sectional views illustrating exemplary operations for manufacturing a light-emitting panel according to another embodiment of the present disclosure, wherein FIG. 13 to FIG. 15 illustrate several operations of manufacturing a circuit level 200.

Referring to FIG. 13, in some embodiments, after the formation of the conductive features 230, the first passivation layer 241 formed on the ILD 203 to cover the conductive features 230 is relatively thick. The first passivation layer 241 includes an inorganic dielectric material in order to be resistant to moisture and acid during subsequent etch operations.

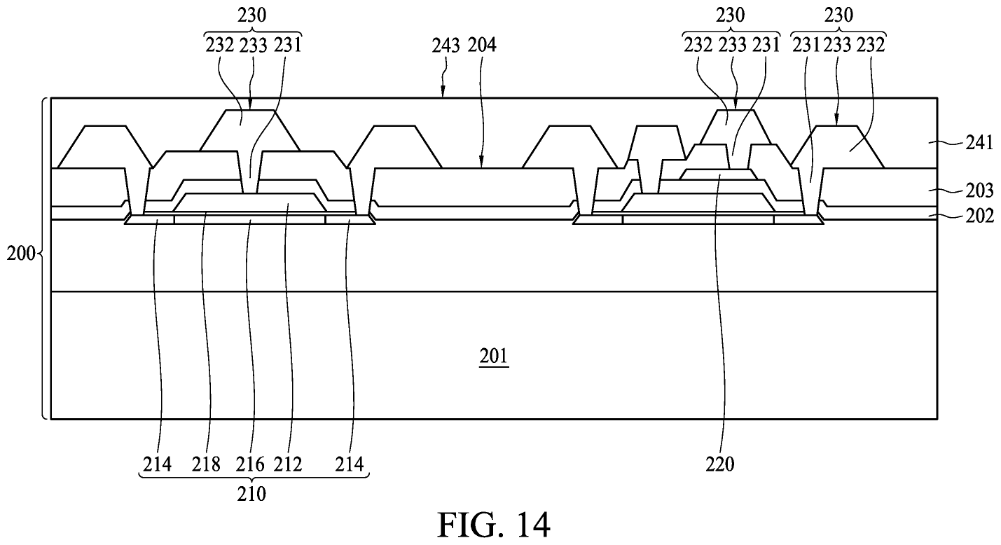

Referring to FIG. 14, in some embodiments, the first passivation layer 241 is planarized, and the top surfaces 243 of the conductive features 230 are covered by the first passivation layer 241 subsequent to the planarizing of the first passivation layer 241.

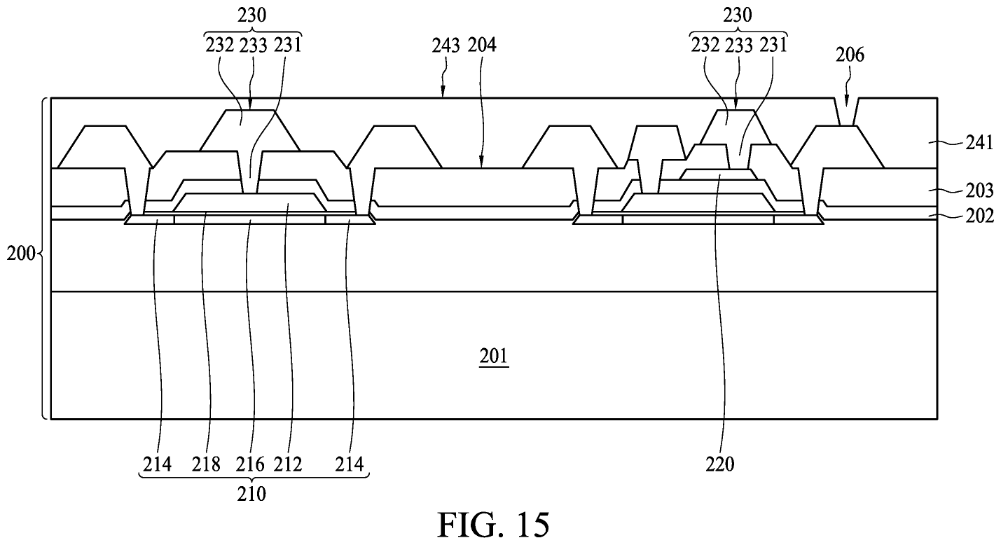

Referring to FIG. 15, in some embodiments, the second through hole 206 is formed in the planarized first passivation layer 241 to penetrate the planarized first passivation layer 241 and partially exposes one of the top surfaces 233 of the conductive feature 230. The second through hole 206 may be formed using a suitable photolithographic mask and etching process, although any suitable process may be used. Because the top surface 243 of the planarized first passivation layer 241 is flat, the second through hole 206 may be more easily formed at the correct predetermined position. In some embodiments, the circuit level 200 is formed.

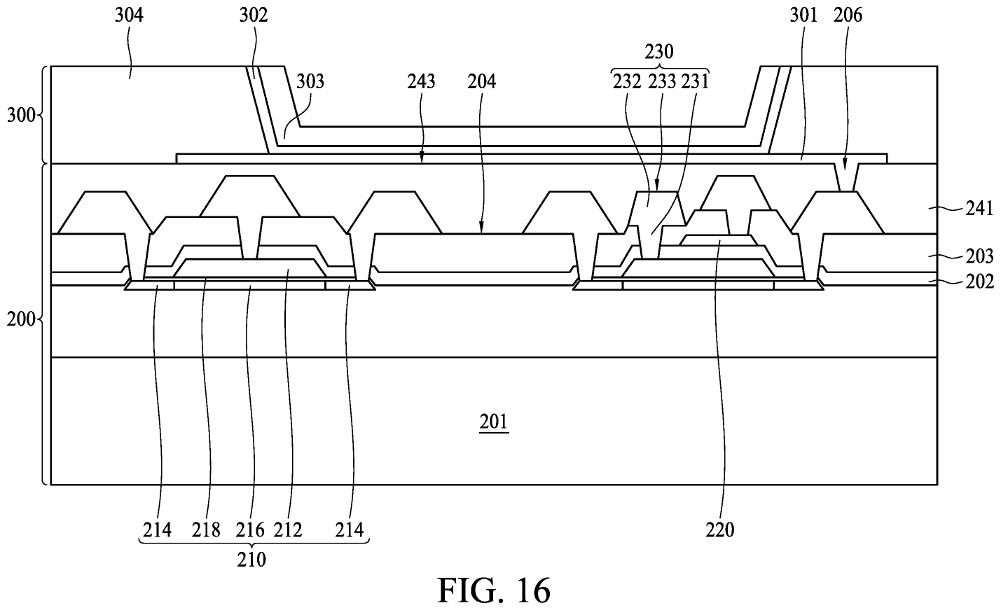

In some embodiments, referring to FIG. 16, the light-emitting device 300 is formed on the planarized first passivation layer 241, and the light-emitting panel is formed. The light-emitting device 300 may include a first electrode 301, a light-emitting layer 302 on the first electrode 301, and a second electrode 303 on the light-emitting layer 302. In some embodiments, the first electrode 301 is formed on and in contact with the top surface 243 of the planarized first passivation layer 241. In some embodiments, no organic passivation layer is disposed between the first electrode 301 and the first passivation layer 241. The first electrode 301 is formed on the planarized first passivation layer 241 and in the second through hole 206 to electrically connect the exposed conductive feature 230. In some embodiments, the light-emitting device 300 further includes a spacer 304 disposed over the planarized first passivation layer 241. The light-emitting device 300 may further include a cover layer (not shown) to cover the spacer 304 and the second electrode 303.

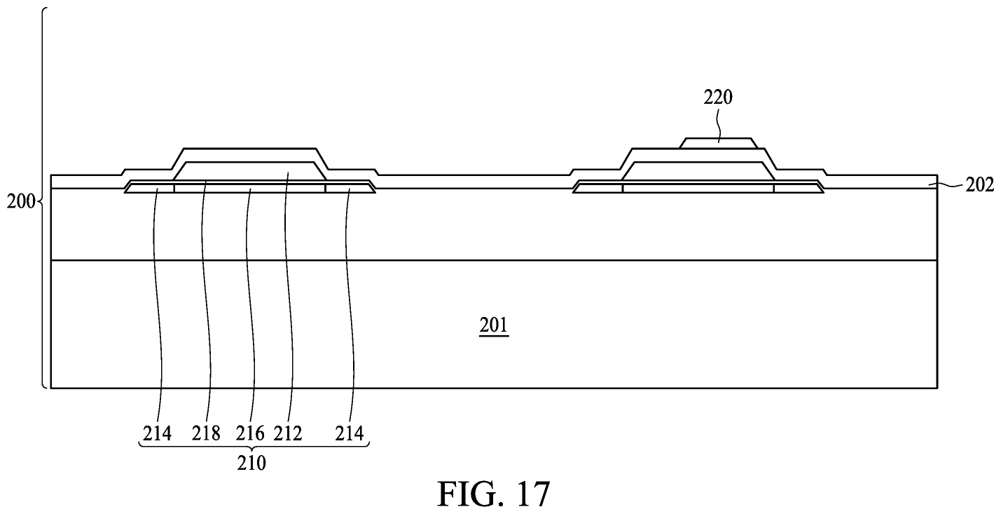

FIGS. 17 to 25 are cross-sectional views illustrating exemplary operations for manufacturing a light-emitting panel according to another embodiment of the present disclosure, wherein FIG. 17 to FIG. 24 illustrate several operations of manufacturing a circuit level 200.

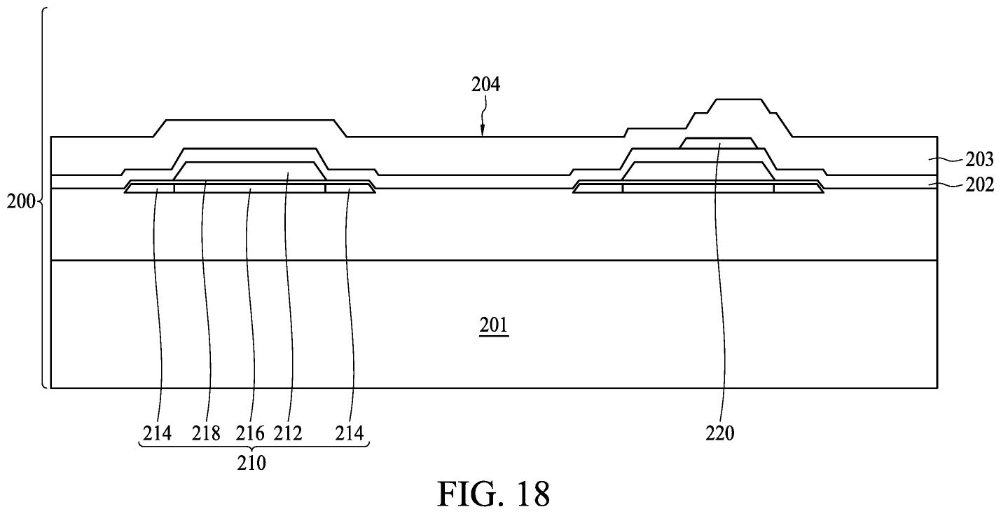

The operations shown in FIGS. 17 and 18 are respectively similar to the operations shown in FIGS. 3 and 4, and are not described again herein. In some embodiments, the ILD 203 shown in FIG. 18 is relatively thicker than the ILD 203 shown in FIG. 4.

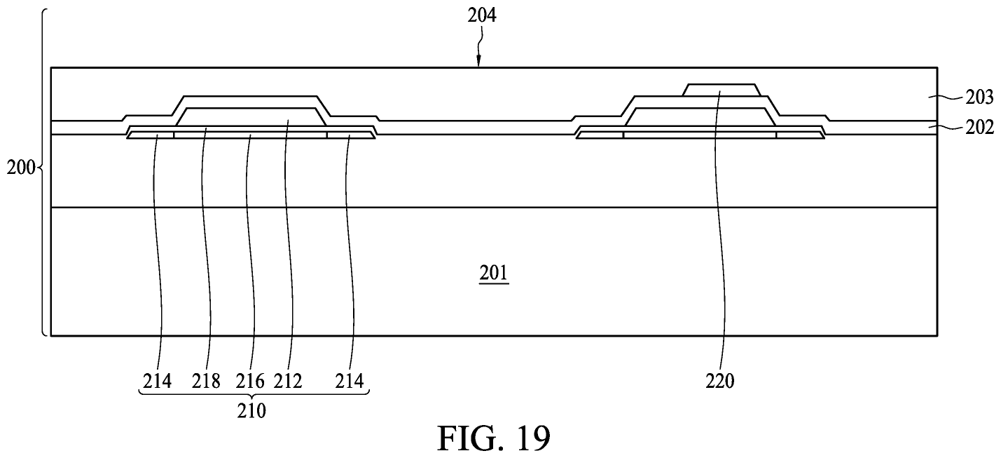

In order to provide a flat surface for subsequent operations, as shown in FIG. 19, the ILD 203 is planarized. The ILD 203 may be planarized using a suitable planarizing process, although any suitable process may be used. In some embodiments, planarizing the ILD 203 includes performing a CMP operation. The top surface 204 of the planarized ILD 203 is flat and has a minimized roughness. In some embodiments, the top surface 204 of the planarized ILD 203 has a surface roughness less than or equal to 100 Å.

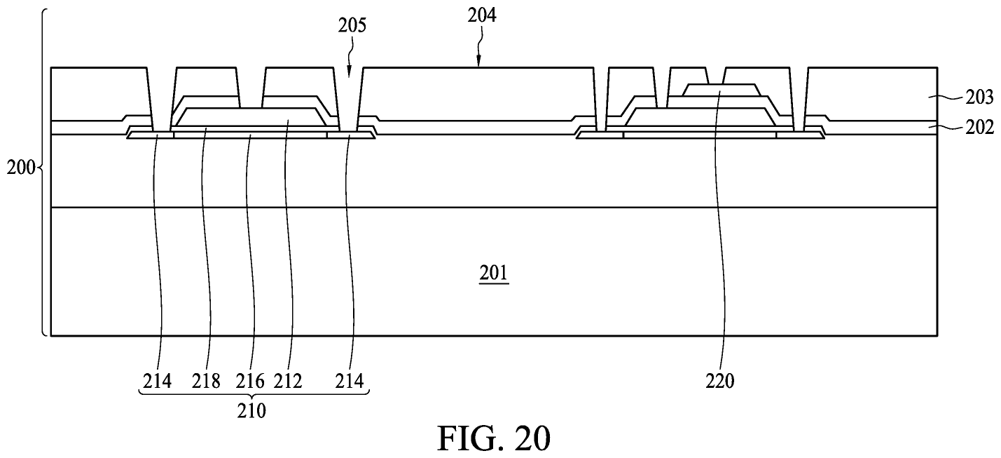

Referring to FIG. 20, the first through holes 205 are formed in the planarized ILD 203 to partially expose the transistors 210. Predetermined portions of the transistors 210 and the storage electrode 220 may be exposed using a suitable photolithographic mask and etching process, although any suitable process may be used. In some embodiments, the depths of the first through holes 205 vary.

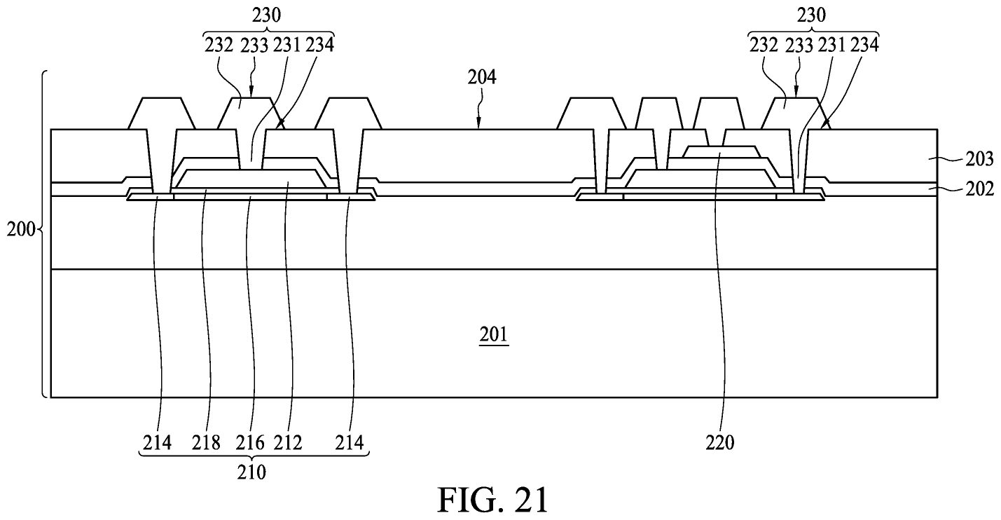

Referring to FIG. 21, the conductive features 230 are formed on the planarized ILD 203 and in the first through holes 205 to electrically connect the transistors 210 and the storage electrode 220. The planarized ILD 203 is disposed between the transistors 210 and the conductive features 230. The conductive features 230 may be formed by various deposition techniques, which are followed by various patterning techniques. In some embodiments, the conductive features 230 are formed on a flat top surface 204 of the planarized ILD 203, and top surfaces 233 of the conductive features 230 are at the same level. In some embodiments, the top surfaces 233 of the conductive features 230 are substantially coplanar. In some embodiments, the bottom surfaces 234 of the conductive traces 232 are at the same level.

In some embodiments, the height of each conductive via 231 may be same or different because the penetration depth of each conductive via 231 is determined by the thickness of the planarized ILD 203 and the films under the planarized ILD 203 at the location where the conductive via 231 is located. For example, the conductive via 231 connected to the gate 212 has a smaller total height than the conductive via 231 connected to the source/drain regions 214 because during the planarizing of the ILD 203, the removed portion of the ILD 203 above the gate 212 is larger than the removed portion of the ILD 203 above the source/drain region 214. In FIG. 21, despite the different height of each of the conductive vias 231, the top surfaces 233 of the conductive features 230 electrically connected to the respective one of the source/drain regions 214, the channel 212 or the storage electrode 220 are at the same level.

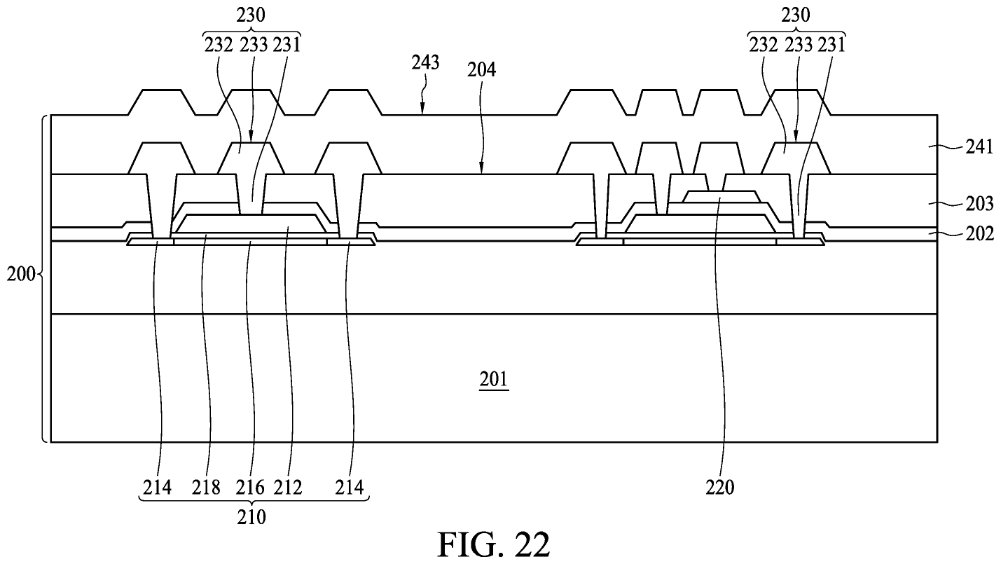

Referring to FIG. 22, the first passivation layer 241 is formed on the planarized ILD 203 to cover the conductive features 230. The first passivation layer 241 includes an inorganic dielectric material in order to be resistant to moisture and acid during subsequent etch operations. In some embodiments, the first passivation layer 241 is conformal to the conductive features 230 and conformal to the exposed and planarized ILD 203. Therefore, a top surface 243 of the first passivation layer 241 is undulating and follows the topography of the conductive traces 232 and the exposed and planarized ILD 203 thereunder. In some embodiments, thickness of the first passivation layer 241 is uniform.

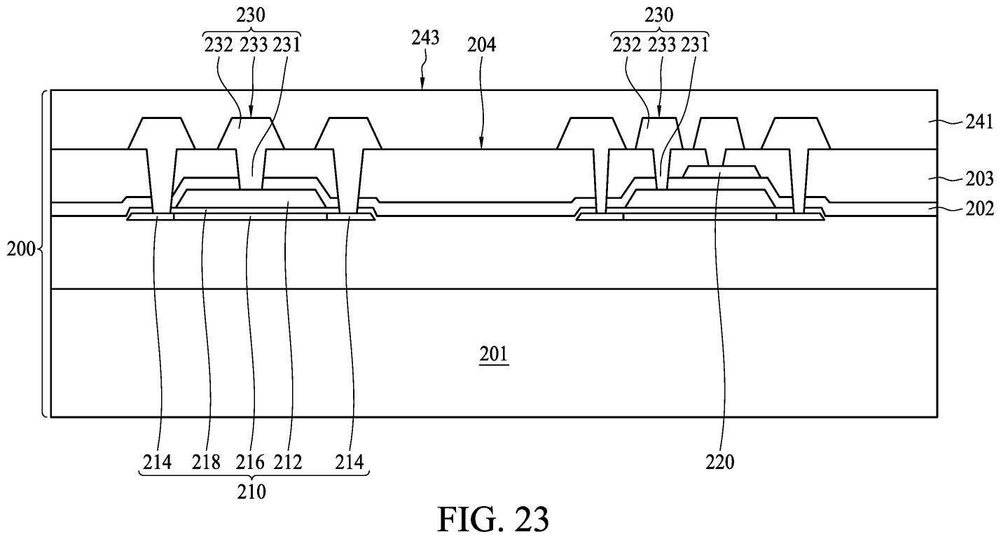

Referring g to FIG. 23, in some embodiments, the first passivation layer 241 is planarized, and the top surfaces 243 of the conductive features 230 are covered by the first passivation layer 241 subsequent to the planarizing of the first passivation layer 241. In some embodiments, the distance from the top surface 233 of each conductive feature 230 to the top surface 243 of the planarized first passivation layer 241 is the same.

In some embodiments, the top surfaces 243 of the conductive features 230 are exposed through the first passivation layer 241 subsequent to the planarizing of the first passivation layer 241, and the second passivation layer 244 is formed on the planarized first passivation layer 241 and the conductive features 230.

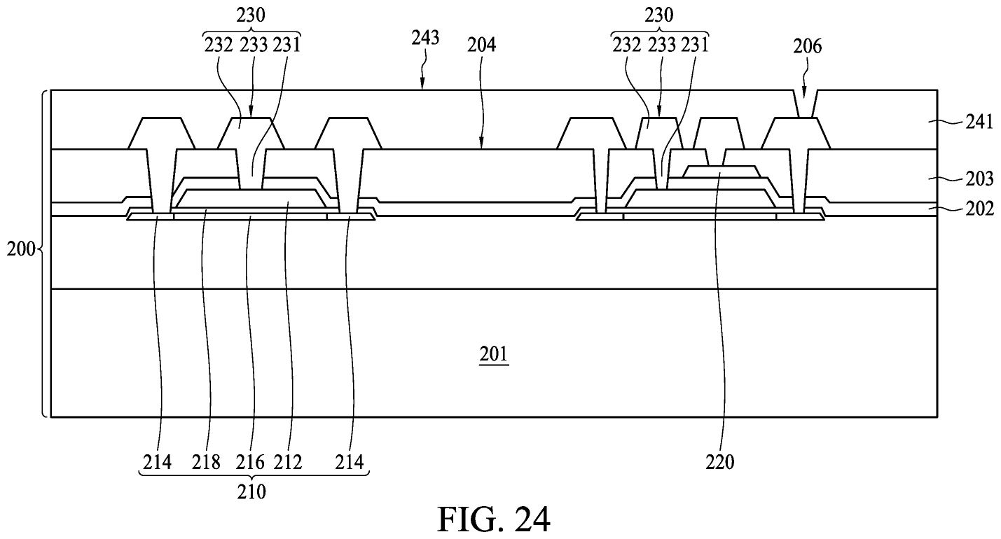

Referring to FIG. 24, in some embodiments, the second through hole 206 is formed in the planarized first passivation layer 241 to penetrate the planarized first passivation layer 241, and partially exposes the top surface 233 of one of the conductive features 230. The second through hole 206 may be formed using a suitable photolithographic mask and etching process, although any suitable process may be used. Since the top surface 243 of the planarized first passivation layer 241 is flat, the second through hole 206 may be more easily formed at the correct predetermined position. In some embodiments, the circuit level 200 is formed.

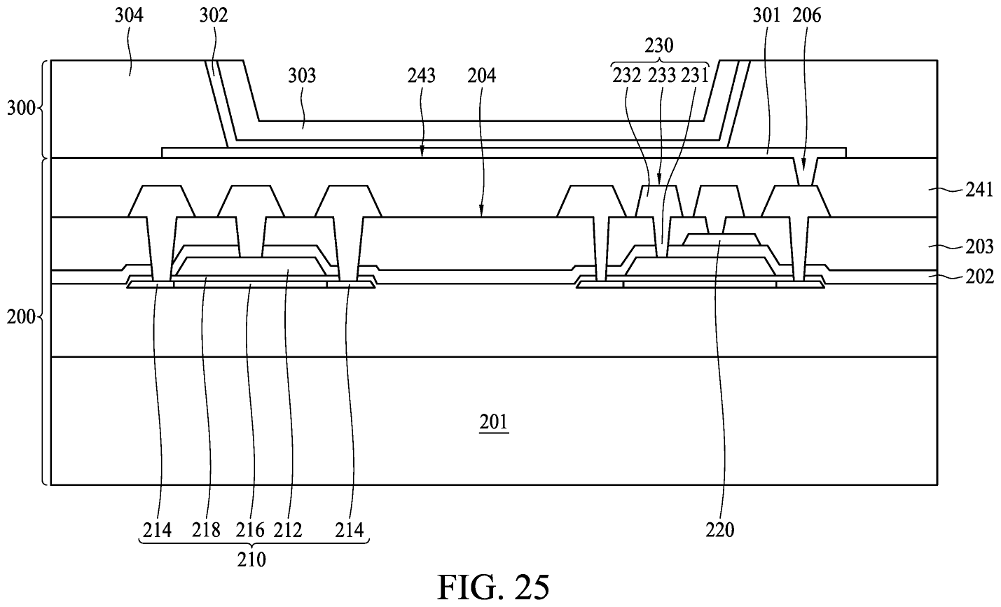

Referring to FIG. 25, in some embodiments, the light-emitting device 300 is formed on the planarized first passivation layer 241, and the light-emitting panel is formed. The light-emitting device 300 may include a first electrode 301, a light-emitting layer 302 on the first electrode 301, and a second electrode 303 on the light-emitting layer 302. The first electrode 301 is formed on and in contact with the top surface 243 of the planarized first passivation layer 241 and in the second through hole 206 to electrically connect the exposed conductive feature 230. In some embodiments, no organic passivation layer is disposed between the first electrode 301 and the first passivation layer 241. The first electrode 301 is formed on the planarized first passivation layer 241 and in the second through hole 206 to electrically connect the exposed conductive feature 230. The light-emitting device 300 may further include a spacer 304 disposed over the planarized first passivation layer 241. In some embodiments, the light-emitting device 300 further includes a cover layer (not shown) to cover the spacer 304 and the second electrode 303.

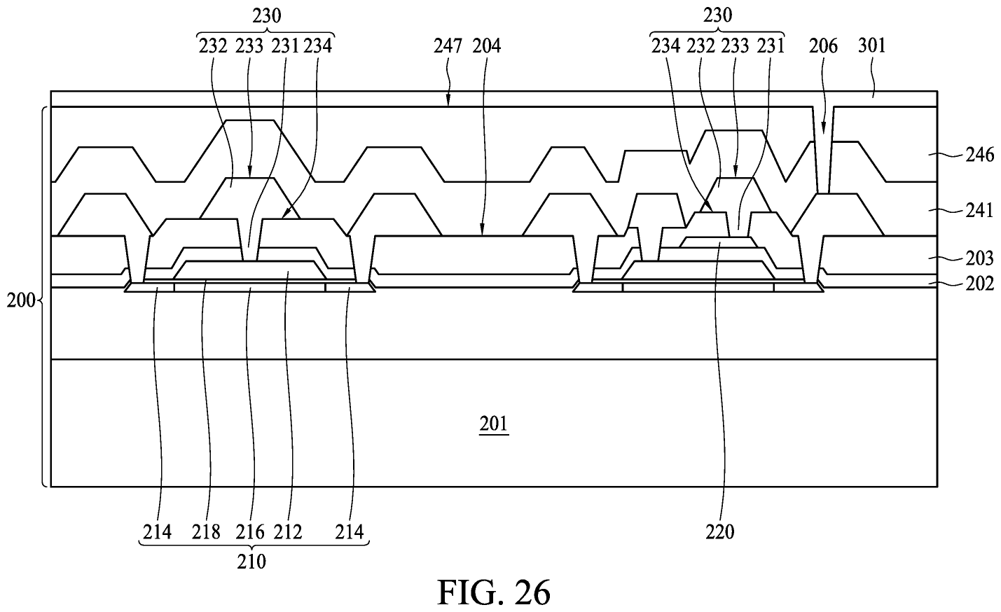

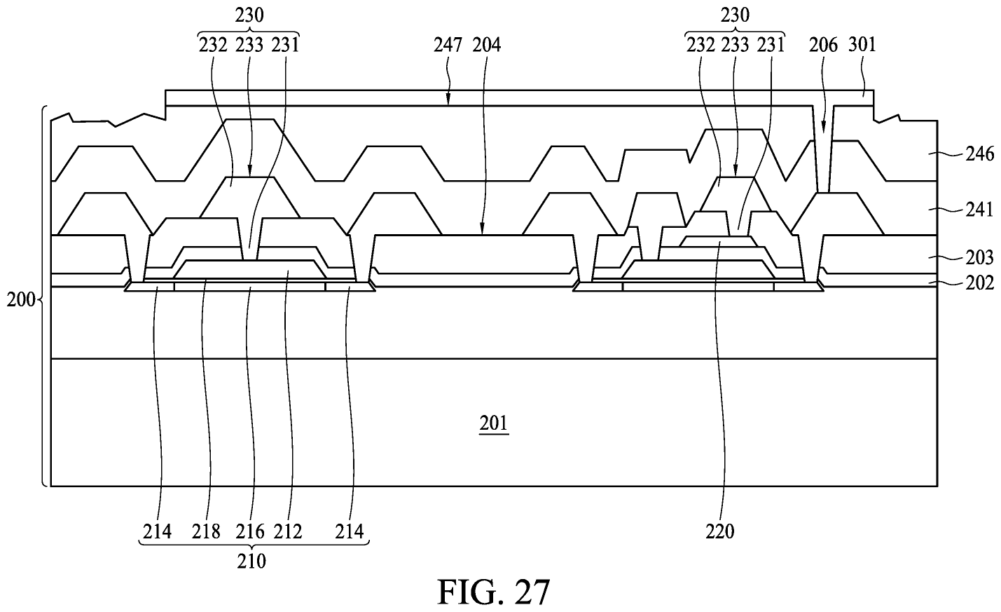

FIG. 26 and FIG. 27 illustrate several operations of a method of manufacturing of a light-emitting panel in accordance with a comparative embodiment.

Referring to FIG. 26, in some embodiments, a planarization layer 246 covers the ILD 203, the transistor 210 and the storage electrode 220, and the planarization layer 246 includes an organic dielectric material. The conductive features 230 are covered by the first passivation layer 241. The top surfaces 233 of the conductive features 230 are at different levels because the levels of the top surfaces 233 are determined by the films under the ILD 203 at the location where the conductive via 231 is located while thickness of the ILD 203 films is made uniform. The bottom surfaces 234 of the conductive features 230 are at different levels for similar reasons. The planarization layer 246 provides a flat surface 247 for subsequent operations. The second through hole 206 is formed in the planarization layer 246 to partially expose one of the conductive features 230. In order to form the first electrode 301, a conductive material is deposited in the second through hole 206 and covers the top surface 247 of the planarization layer 246.

The planarization layer 246 can be formed by various methods. In some embodiments, the planarization layer 246 is formed by spin coating an organic dielectric material over the first passivation layer 241, curing the organic dielectric material, and planarizing the cured organic dielectric material. In some embodiments, compared to the layers formed by deposition, such as the first passivation layer 241 and the second passivation layer 244, the planarization layer 246 including the organic dielectric material may be thicker, and the circuit level 200 thus formed therefore has a relatively greater thickness.

Referring to FIG. 27, in some embodiments, the electrode 301 is patterned by dry etching. However, it is difficult to control the exact depth of the etch process, and a portion of the planarization layer 246 may be etched away as well. In some embodiments, the planarization layer 246 is damaged by O₂ plasma, the by-product of dry etching such as hydrochloric acid, and/or the photoresist stripping solution.

It is worth noting that, the surface roughness described above may be, for example but not limited to, the arithmetic average roughness Ra. In some embodiments, the surface roughness described above may be represented by other surface roughness parameters such as the root mean squared roughness Rq, the maximum peak-to-valley height Ry, the average peak-to-valley roughness Rtm, or other types of surface roughness parameters without departing from the scope of the present disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein, may be utilized according to the present invention. Accordingly, the appended claims are intended to include within their scope such processes, machines, manufacture, compositions of matter, means, methods and steps.

What is claimed is:

1. A method of manufacturing a light-emitting panel, comprising:
forming a plurality of transistors on a substrate;
forming an inter-layer dielectric (ILD) on the substrate to cover the transistors;
forming a plurality of first through holes penetrating the ILD to partially expose the transistors;
forming a plurality of conductive features on the ILD and in the first through holes to electrically connect the transistors;
forming a first passivation layer on the ILD to cover the conductive features;
planarizing the first passivation layer;
forming a second through hole penetrating the first passivation layer to partially expose one of the conductive features; and
forming a light-emitting device on the planarized first passivation layer, wherein the light-emitting device comprises a first electrode, a light-emitting layer on the first electrode, and a second electrode on the light-emitting layer, and the first electrode is formed on the planarized first passivation layer and in the second through hole to electrically connect the exposed conductive feature.

2. The method of claim 1, wherein the substrate comprises a transparent substrate.

3. The method of claim 1, wherein the first passivation layer includes an inorganic dielectric material.

4. The method of claim 1, wherein the planarizing of the first passivation layer comprises performing a chemical-mechanical planarization operation.

5. The method of claim 1, wherein the forming of the first passivation layer comprises performing a deposition operation.

6. The method of claim 1, wherein top surfaces of the conductive features are covered by the first passivation layer subsequent to the planarizing of the first passivation layer.

7. The method of claim 1, wherein top surfaces of the conductive features are exposed through the first passivation layer subsequent to the planarizing of the first passivation layer.

8. The method of claim 7, wherein portions of the conductive features are removed simultaneously with the first passivation layer during the planarizing of the first passivation layer.

9. The method of claim 7, further comprising:
forming a second passivation layer on the planarized first passivation layer and the conductive features prior to formation of the second through hole;
planarizing the second passivation layer; and
forming the second through hole penetrating the second passivation layer.

10. The method of claim 9, wherein the planarizing of the second passivation layer comprises performing a chemical-mechanical planarization operation.

11. The method of claim 1, further comprising planarizing the ILD prior to formation of the first through holes in the ILD.

12. The method of claim 11, wherein the planarizing of the ILD comprises performing a chemical-mechanical planarization operation.

13. The method of claim 1, further comprising forming a storage electrode on one of the transistors.

14. The method of claim 1, wherein the substrate includes a round substrate compatible with semiconductor fabrication.

15. A method of manufacturing a light-emitting panel, comprising:
forming a plurality of transistors on a substrate;
forming an inter-layer dielectric (ILD) on the substrate to cover the transistors;
planarizing the ILD;
forming a plurality of first through holes penetrating the ILD to partially expose the transistors;
forming a plurality of conductive features on the ILD and in the first through holes to electrically connect the transistors;
forming a first passivation layer on the ILD to cover the conductive features;
planarizing the first passivation layer;
forming a second through hole penetrating the first passivation layer to partially expose one of the conductive features; and
forming a light-emitting device on the first passivation layer, wherein the light-emitting device comprises a first electrode, a light-emitting layer on the first electrode, and a second electrode on the light-emitting layer, and wherein the first electrode is formed on the first passivation layer and in the second through hole to electrically connect the exposed conductive feature.

16. The method of claim 15, wherein the substrate comprises a transparent substrate.

17. The method of claim 15, wherein the planarizing of the ILD comprises performing a chemical-mechanical planarization operation.

18. The method of claim 15, wherein the ILD includes an inorganic dielectric material.

19. The method of claim 15, further comprising forming a storage electrode on one of the transistors.

20. A light-emitting panel, comprising:
a circuit level including a passivation layer, wherein the passivation layer includes an inorganic dielectric material; and
a light-emitting device disposed on a top surface of the passivation layer and electrically connected to the circuit level.

21. The light-emitting panel of claim 20, wherein the light-emitting device includes a first electrode, and the first electrode is in contact with the top surface of the passivation layer.

22. The light-emitting panel of claim 20, wherein the circuit level further includes a transistor, a capacitor, and a plurality of conductive features, wherein each of the conductive features comprises a conductive via disposed in the passivation layer and electrically connected to the transistor or the capacitor, and a conductive trace disposed on the top surface of the passivation layer and electrically connected to the conductive via.

23. The light-emitting panel of claim 22, wherein top surfaces of the conductive traces are substantially at the same level.

24. The light-emitting panel of claim 22, wherein bottom surfaces of the conductive traces are substantially at the same level.

25. The light-emitting panel of claim 22, wherein the circuit level further includes an inter-layer dielectric covering the conductive traces, and a top surface of the inter-layer dielectric has a surface roughness less than or equal to 100 Å.

26. The light-emitting panel of claim 22, wherein the top surface of the conductive feature has a surface roughness less than or equal to 100 Å.

27. The light-emitting panel of claim 20, wherein the top surface of the passivation layer has a surface roughness less than or equal to 100 Å.
